(19) United States
(12) Patent Application Publication
(10) Pub. No.: US 2025/0011926 A1
(43) Pub. Date: Jan. 9, 2025

(54) SUBSTRATE PROCESSING METHOD, METHOD OF MANUFACTURING SEMICONDUCTOR DEVICE, NON-TRANSITORY COMPUTER-READABLE RECORDING MEDIUM AND SUBSTRATE PROCESSING APPARATUS

(71) Applicant: KOKUSAI ELECTRIC CORPORATION, Tokyo (JP)

(72) Inventor: Arito OGAWA

(73) Assignee: KOKUSAI ELECTRIC CORPORATION, Tokyo (JP)

(21) Appl. No.: 18/895,787

(22) Filed: Sep. 25, 2024

Related U.S. Application Data
(63) Continuation of application No. PCT/JP2022/015579, filed on Mar. 29, 2022.

(51) Int. Cl. C23C 16/44; C23C 16/52; H01L 21/67

(52) U.S. Cl. CPC C23C 16/4408; C23C 16/52; H01L 21/67017

(57) ABSTRACT

It is possible to improve characteristics of a film formed on a substrate. There is provided a technique that includes: (a) performing a first supply of a source gas containing a first element and a halogen element to a substrate; (b) performing a supply of a first reducing gas to the substrate; (c) performing a supply of a second reducing gas to the substrate; (d) performing a second supply of the source gas to the substrate, (e) executing (b) and (d) X times without performing a purge between (b) and (d); and (f) executing (e) and (c) Y times.

### CROSS-REFERENCE TO RELATED PATENT APPLICATION

This application is a bypass continuation application of PCT International Application No. PCT/JP2022/015579, filed on Mar. 29, 2022, in the WIPO, the entire contents of which are hereby incorporated by reference.

### 1. FIELD

The present disclosure relates to a substrate processing method, a method of manufacturing a semiconductor device, a non-transitory computer-readable recording medium and a substrate processing apparatus.

### 2. RELATED ART

For example, a metal film whose resistance is low is used as a word line of a DRAM or a 3D NAND flash memory of a three-dimensional structure. Further, according to some related arts, a barrier film may be formed between the metal film and an insulating film.

### SUMMARY OF THE INVENTION

According to the present disclosure, there is provided a technique capable of improving characteristics of a film formed on a substrate.

According to an embodiment of the present disclosure, there is provided a technique that includes: (a) performing a first supply of a source gas containing a first element and a halogen element to a substrate; (b) performing a supply of a first reducing gas to the substrate; (c) performing a supply of a second reducing gas to the substrate; (d) performing a second supply of the source gas to the substrate, (e) executing (b) and (d) X times without performing a purge between (b) and (d); and (f) executing (e) and (c) Y times.

### BRIEF DESCRIPTION OF THE DRAWINGS

FIG. 1 is a diagram schematically illustrating a vertical cross-section of a vertical type process furnace of a substrate processing apparatus according to one or more embodiments of the technique of the present disclosure.

FIG. 2 is a diagram schematically illustrating a horizontal cross-section taken along a line A-A of the substrate processing apparatus shown in FIG. 1.

FIG. 3 is a block diagram schematically illustrating a configuration of a controller and related components of the substrate processing apparatus according to the embodiments of the present disclosure.

FIG. 4 is a diagram schematically illustrating a substrate processing sequence according to the embodiments of the present disclosure.

FIG. 5 is a diagram schematically illustrating a modified example of the substrate processing sequence according to the embodiments of the present disclosure.

### DETAILED DESCRIPTION

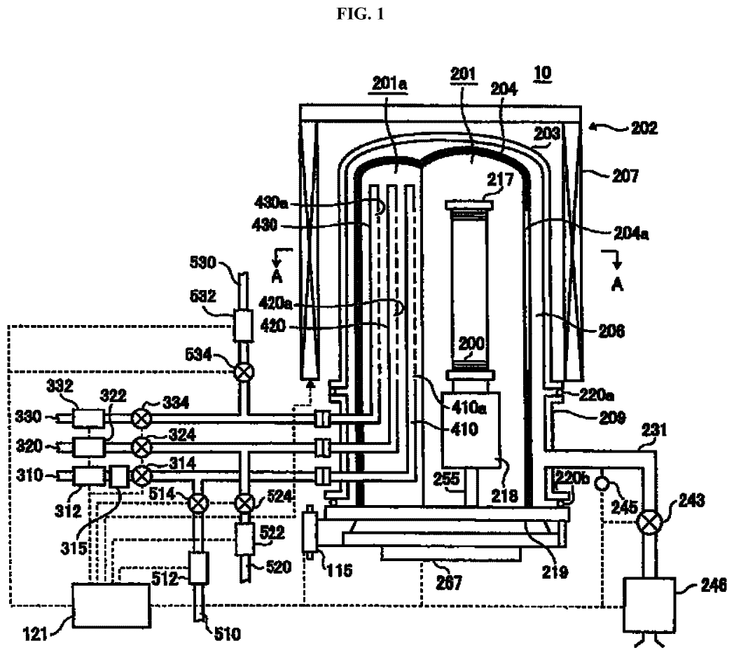

Hereinafter, one or more embodiments (also simply referred to as “embodiments”) according to the technique of the present disclosure will be described with reference to FIGS. 1 to 4. The drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match.

### (1) Configuration of Substrate Processing Apparatus

A substrate processing apparatus 10 according to the present embodiments includes a process furnace 202 (for example, a vertical type process furnace) provided with a heater 207 serving as a heating structure (which is a heating device or a heating system). The heater 207 is of a cylindrical shape, and is vertically installed while being supported by a heater base (not shown) serving as a support plate.

An outer tube 203 constituting a process vessel is provided in an inner side of the heater 207 to be aligned in a manner concentric with the heater 207. For example, the outer tube 203 is made of a heat resistant material such as quartz (SiO₂) and silicon carbide (SiC). For example, the outer tube 203 is of a cylindrical shape with a closed upper end and an open lower end. A manifold (which is an inlet flange) 209 is provided under the outer tube 203 to be aligned in a manner concentric with the outer tube 203. For example, the manifold 209 is made of a metal such as stainless steel (SUS). For example, the manifold 209 is of a cylindrical shape with open upper and lower ends. An O-ring 220a serving as a seal is provided between the upper end of the manifold 209 and the outer tube 203. As the manifold 209 is supported by the heater base (not shown), the outer tube 203 is installed vertically.

An inner tube 204 constituting the process vessel is provided in an inner side of the outer tube 203. For example, the inner tube 204 is made of a heat resistant material such as quartz (SiO₂) and silicon carbide (SiC). For example, the inner tube 204 is of a cylindrical shape with a closed upper end and an open lower end. The process vessel is constituted mainly by the outer tube 203, the inner tube 204 and the manifold 209. A process chamber 201 is provided in a hollow cylindrical portion of the process vessel (that is, an inside of the inner tube 204).

The process chamber 201 is configured to be capable of accommodating a plurality of wafers including a wafer 200 serving as a substrate in a horizontal orientation to be vertically arranged in a multistage manner by a boat 217 described later. Hereinafter, the plurality of wafers including the wafer 200 may also be simply referred to as wafers 200.

Nozzles 410, 420 and 430 are installed in the process chamber 201 so as to penetrate a side wall of the manifold 209 and the inner tube 204. Gas supply pipe 310, 320 and 330 are connected to the nozzles 410, 420 and 430, respectively. However, the process furnace 202 of the present embodiments is not limited to the example described above.

Mass flow controllers (MFCs) 312, 322 and 332 serving as flow rate controllers (flow rate control structures) and valves 314, 324 and 334 serving as opening/closing valves are sequentially installed at the gas supply pipes 310, 320 and 330 in this order from upstream sides to downstream sides of the gas supply pipes 310, 320 and 330, respectively. Further, a storage 315 configured to store a gas is provided at the gas supply pipe 310 between the MFC 312 and the valve 314, that is, at a downstream side of the MFC 312 and an upstream side of the valve 314. That is, a predetermined amount of the gas is stored in the storage 315 before the gas is supplied such that the gas stored in the storage 315 can be used when the gas is supplied. Further, gas supply pipes 510, 520 and 530 through which an inert gas is supplied are connected to the gas supply pipes 310, 320 and 330 at downstream sides of the valves 314, 324 and 334, respectively. MFCs 512, 522 and 532 serving as flow rate controllers (flow rate control structures) and valves 514, 524 and 534 serving as opening/closing valves are sequentially installed at the gas supply pipes 510, 520 and 530 in this order from upstream sides to downstream sides of the gas supply pipes 510, 520 and 530, respectively.

The nozzles 410, 420 and 430 are connected to front ends (tips) of the gas supply pipes 310, 320 and 330, respectively. Each of the nozzles 410, 420 and 430 is configured as an L-shaped nozzle. Horizontal portions of the nozzles 410, 420 and 430 are installed so as to penetrate the side wall of the manifold 209 and the inner tube 204. Vertical portions of the nozzles 410, 420 and 430 are installed in a preliminary chamber 201a of a channel shape (a groove shape) protruding outward in a radial direction of the inner tube 204 and extending in the vertical direction. That is, the vertical portions of the nozzles 410, 420 and 430 are installed in the preliminary chamber 201a to extend toward the upper end of the inner tube 204 (in an upward direction in which the wafers 200 are arranged) and along an inner wall of the inner tube 204.

The nozzles 410, 420 and 430 extend from a lower region of the process chamber 201 to an upper region of the process chamber 201. The nozzles 410, 420 and 430 are provided with a plurality of gas supply holes 410a, a plurality of gas supply holes 420a and a plurality of gas supply holes 430a, respectively, at positions facing the wafers 200. Thereby, the gas such as a process gas can be supplied to the wafers 200 through the gas supply holes 410a of the nozzle 410, the gas supply holes 420a of the nozzle 420 and the gas supply holes 430a of the nozzle 430. The gas supply holes 410a, the gas supply holes 420a and the gas supply holes 430a are provided from a lower portion to an upper portion of the inner tube 204. An opening area of each of the gas supply holes 410a, the gas supply holes 420a and the gas supply holes 430a is the same, and each of the gas supply holes 410a, the gas supply holes 420a and the gas supply holes 430a is provided at the same pitch. However, the gas supply holes 410a, the gas supply holes 420a and the gas supply holes 430a are not limited thereto. For example, the opening area of each of the gas supply holes 410a, the gas supply holes 420a and the gas supply holes 430a may gradually increase from the lower portion to the upper portion of the inner tube 204 to further uniformize a flow rate of the gas supplied through the gas supply holes 410a, the gas supply holes 420a and the gas supply holes 430a.

The gas supply holes 410a of the nozzle 410, the gas supply holes 420a of the nozzle 420 and the gas supply holes 430a of the nozzle 430 are provided from a lower portion to an upper portion of the boat 217 described later. Therefore, the process gas (which is supplied into the process chamber 201 through the gas supply holes 410a, the gas supply holes 420a and the gas supply holes 430a) is supplied onto the wafers 200 accommodated in the boat 217 from the lower portion to the upper portion thereof, that is, the entirety of the wafers 200 accommodated in the boat 217. It is preferable that the nozzles 410, 420 and 430 extend from the lower region to the upper region of the process chamber 201. However, the nozzles 410, 420 and 430 may extend only to the vicinity of a ceiling of the boat 217.

A source gas containing a first element and a halogen element and serving as one of process gases is supplied into the process chamber 201 through the gas supply pipe 310 provided with the MFC 312, the storage 315, the valve 314 and the nozzle 410.

A first reducing gas serving as one of the process gases is supplied into the process chamber 201 through the gas supply pipe 320 provided with the MFC 322 and the valve 324 and the nozzle 420.

A second reducing gas serving as one of the process gases is supplied into the process chamber 201 through the gas supply pipe 330 provided with the MFC 332 and the valve 334 and the nozzle 430. In the present embodiments, the second reducing gas is used as a reactive gas reactable with the source gas.

The inert gas such as nitrogen (N₂) gas is supplied into the process chamber 201 through the gas supply pipes 510, 520 and 530 provided with the MFCs 512, 522 and 532 and the valves 514, 524 and 534, respectively, and the nozzles 410, 420 and 430. While the present embodiments will be described by way of an example in which the N₂ gas is used as the inert gas, the inert gas according to the present embodiments is not limited thereto. For example, as the inert gas, instead of or in addition to the N₂ gas, a rare gas such as argon (Ar) gas, helium (He) gas, neon (Ne) gas and xenon (Xe) gas may be used.

A process gas supplier (which is a process gas supply structure or a process gas supply system) is constituted mainly by the gas supply pipes 310, 320 and 330, the MFCs 312, 322 and 332, the valves 314, 324 and 334 and the nozzles 410, 420 and 430. However, the nozzles 410, 420 and 430 alone may be referred to as the “process gas supplier”. The process gas supplier may also be simply referred to as a “gas supplier” which is a gas supply structure or a gas supply system. When the source gas is supplied through the gas supply pipe 310, a source gas supplier (which is a source gas supply structure or a source gas supply system) is constituted mainly by the gas supply pipe 310, the MFC 312, the storage 315 and the valve 314. However, the source gas supplier may further include the nozzle 410. Further, when the first reducing gas is supplied through the gas supply pipe 320, a first reducing gas supplier (which is a first reducing gas supply structure or a first reducing gas supply system) is constituted mainly by the gas supply pipe 320, the MFC 322 and the valve 324. However, the first reducing gas supplier may further include the nozzle 420. Further, when the second reducing gas is supplied through the gas supply pipe 330, a second reducing gas supplier (which is a second reducing gas supply structure or a second reducing gas supply system) is constituted mainly by the gas supply pipe 330, the MFC 332 and the valve 334. However, the second reducing gas supplier may further include the nozzle 430. When the second reducing gas serving as the reactive gas is supplied through the gas supply pipe 330, the second reducing gas supplier may also be simply referred to as a “reactive gas supplier” which is a reactive gas supply structure or a reactive gas supply system. In addition, an inert gas supplier (which is an inert gas supply structure or an inert gas supply system) is constituted mainly by the gas supply pipes 510, 520 and 530, the MFCs 512, 522 and 532 and the valves 514, 524 and 534.

According to the present embodiments, the gas is supplied into a vertically long annular space which is defined by the inner wall of the inner tube 204 and edges (peripheries) of the wafers 200 through the nozzles 410, 420 and 430 provided in the preliminary chamber 201a. Then, the gas is ejected into the inner tube 204 through the gas supply holes 410a of the nozzle 410, the gas supply holes 420a of the nozzle 420 and the gas supply holes 430a of the nozzle 430 open toward the wafers 200. Specifically, the gases such as the process gas are ejected into the inner tube 204 in a direction parallel to surfaces of the wafers 200 through the gas supply holes 410a of the nozzle 410, the gas supply holes 420a of the nozzle 420 and the gas supply holes 430a of the nozzle 430, respectively.

An exhaust hole (which is an exhaust port) 204a is a through-hole facing the nozzles 410, 420 and 430, and is provided at a side wall of the inner tube 204. For example, the exhaust hole 204a may be of a narrow slit-shaped through-hole elongating vertically. The gas supplied into the process chamber 201 through the gas supply holes 410a of the nozzle 410, the gas supply holes 420a of the nozzle 420 and the gas supply holes 430a of the nozzle 430 flows over the surfaces of the wafers 200. The gas that has flowed over the surfaces of the wafers 200 is exhausted through the exhaust hole 204a into a gap (that is, an exhaust path 206) provided between the inner tube 204 and the outer tube 203. The gas flowing in the exhaust path 206 flows into an exhaust pipe 231 and is then discharged (exhausted) out of the process furnace 202.

The exhaust hole 204a is provided to face the wafers 200. The gas supplied in the vicinity of the wafers 200 in the process chamber 201 through the gas supply holes 410a, the gas supply holes 420a and the gas supply holes 430a flows in the horizontal direction. Then, the gas that has flowed in the horizontal direction is exhausted through the exhaust hole 204a into the exhaust path 206. The exhaust hole 204a is not limited to the slit-shaped through-hole. For example, the exhaust hole 204a may be configured as a plurality of holes.

The exhaust pipe 231 through which an inner atmosphere of the process chamber 201 is exhausted is installed at the manifold 209. A pressure sensor 245 serving as a pressure detector (pressure detecting structure) configured to detect an inner pressure of the process chamber 201, an APC (Automatic Pressure Controller) valve 243 and a vacuum pump 246 serving as a vacuum exhaust apparatus are sequentially installed at the exhaust pipe 231 in this order from an upstream side to a downstream side of the exhaust pipe 231. With the vacuum pump 246 in operation, the APC valve 243 may be opened or closed to perform a vacuum exhaust of the process chamber 201 or stop the vacuum exhaust. Further, with the vacuum pump 246 in operation, an opening degree of the APC valve 243 may be adjusted in order to adjust the inner pressure of the process chamber 201. An exhauster (which is an exhaust structure or an exhaust system) is constituted mainly by the exhaust hole 204a, the exhaust path 206, the exhaust pipe 231, the APC valve 243 and the pressure sensor 245. The exhauster may further include the vacuum pump 246.

A seal cap 219 serving as a furnace opening lid capable of airtightly sealing a lower end opening of the manifold 209 is provided under the manifold 209. The seal cap 219 is in contact with the lower end of the manifold 209 from thereunder. For example, the seal cap 219 is made of a metal such as SUS, and is of a disk shape. An O-ring 220b serving as a seal is provided on an upper surface of the seal cap 219 so as to be in contact with the lower end of the manifold 209. A rotator (which is a rotating structure) 267 configured to rotate the boat 217 accommodating the wafers 200 is provided at the seal cap 219 in a manner opposite to the process chamber 201. A rotating shaft 255 of the rotator 267 is connected to the boat 217 through the seal cap 219. As the rotator 267 rotates the boat 217, the wafers 200 are rotated. The seal cap 219 may be elevated or lowered in the vertical direction by a boat elevator 115 serving as an elevating structure vertically provided outside the outer tube 203. When the seal cap 219 is elevated or lowered in the vertical direction by the boat elevator 115, the boat 217 may be transferred (loaded) into the process chamber 201 or transferred (unloaded) out of the process chamber 201. The boat elevator 115 serves as a transfer device (which is a transfer structure or a transfer system) that loads the boat 217 and the wafers 200 accommodated in the boat 217 into the process chamber 201 or unloads the boat 217 and the wafers 200 accommodated in the boat 217 out of the process chamber 201.

The boat 217 serving as a substrate support is configured to accommodate (or support) the wafers 200 (for example, 25 to 200 wafers) while the wafers 200 are horizontally oriented with their centers aligned with one another with a predetermined interval therebetween in the vertical direction. For example, the boat 217 is made of a heat resistant material such as quartz and SiC. A plurality of heat insulating plates 218 (which are horizontally oriented) are placed under the boat 217 in a multistage manner (not shown). Each of the heat insulating plates 218 is made of a heat resistant material such as quartz and SiC. With such a configuration, the heat insulating plates 218 suppress the transmission of the heat from the heater 207 to the seal cap 219. However, the present embodiments are not limited thereto. For example, instead of the heat insulating plates 218, a heat insulating cylinder (not shown) such as a cylinder made of a heat resistant material such as quartz and SiC may be provided under the boat 217.

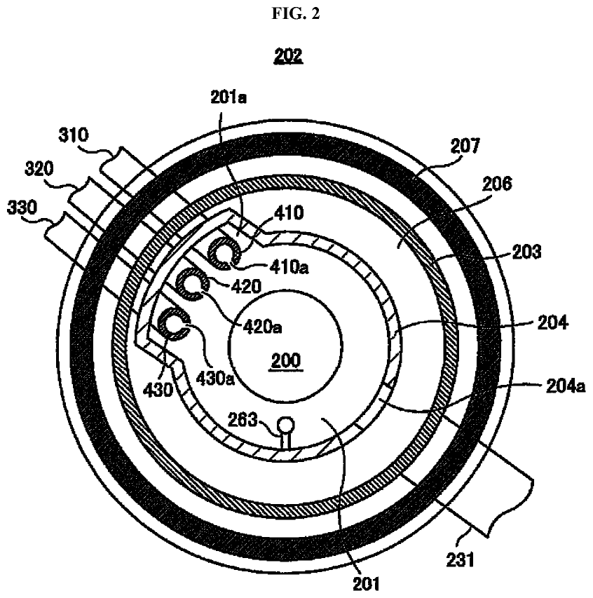

As shown in FIG. 2, a temperature sensor 263 serving as a temperature detector is installed in the inner tube 204. An amount of the current supplied (or applied) to the heater 207 is adjusted based on temperature information detected by the temperature sensor 263 such that a desired temperature distribution of an inner temperature of the process chamber 201 can be obtained. Similar to the nozzles 410, 420 and 430, the temperature sensor 263 is L-shaped, and is provided along the inner wall of the inner tube 204.

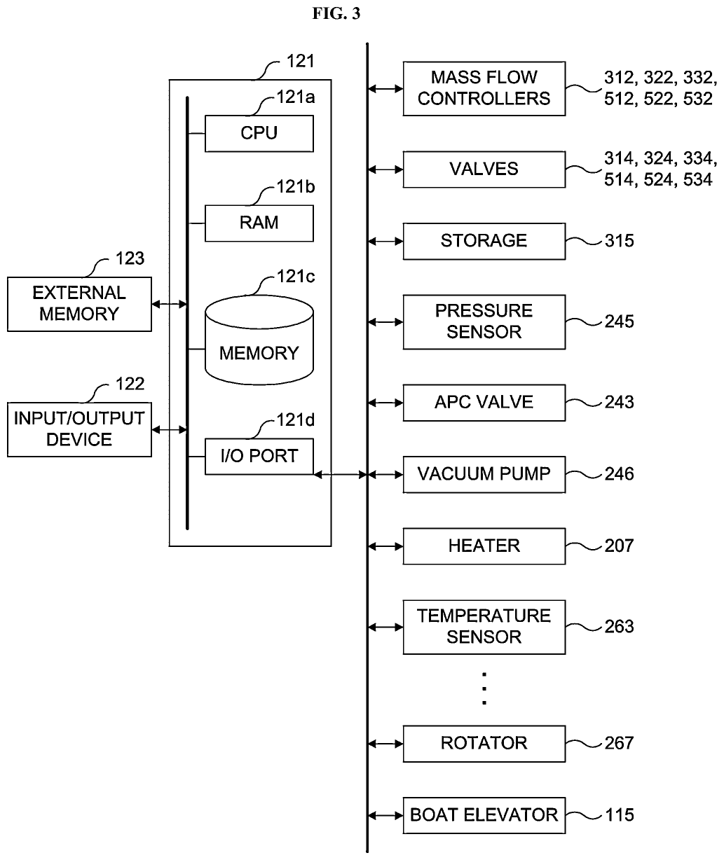

As shown in FIG. 3, a controller 121 serving as a control device (or a control structure) is constituted by a computer including a CPU (Central Processing Unit) 121a, a RAM (Random Access Memory) 121b, a memory 121c and an I/O port 121d. The RAM 121b, the memory 121c and the I/O port 121d may exchange data with the CPU 121a through an internal bus (not shown). For example, an input/output device 122 constituted by a component such as a touch panel is connected to the controller 121.

The memory 121c is configured by a component such as a flash memory and a hard disk drive (HDD). For example, a control program configured to control an operation of the substrate processing apparatus 10 or a process recipe containing information on procedures and conditions of a method of manufacturing a semiconductor device (that is, a substrate processing method) described later is readably stored in the memory 121c. The process recipe is obtained by combining steps of the method of manufacturing the semiconductor device described later such that the controller 121 can execute the steps to acquire a predetermined result, and functions as a program. Hereafter, the process recipe and the control program may be collectively or individually referred to as a “program”. Thus, in the present specification, the term “program” may refer to the process recipe alone, may refer to the control program alone, or may refer to a combination of the process recipe and the control program. The RAM 121b functions as a memory area (work area) where a program or data read by the CPU 121a is temporarily stored.

The I/O port 121d is connected to the components described above such as the MFCs 312, 322, 332, 512, 522 and 532, the valves 314, 324, 334, 514, 524 and 534, the storage 315, the pressure sensor 245, the APC valve 243, the vacuum pump 246, the heater 207, the temperature sensor 263, the rotator 267 and the boat elevator 115.

The CPU 121a is configured to read the control program from the memory 121c and execute the read control program. In addition, the CPU 121a is configured to read a recipe such as the process recipe from the memory 121c in accordance with an operation command inputted from the input/output device 122. In accordance with the contents of the read recipe, the CPU 121a may be configured to control various operations such as flow rate adjusting operations for various gases by the MFCs 312, 322, 332, 512, 522 and 532, opening and closing operations of the valves 314, 324, 334, 514, 524 and 534, an operation of storing the source gas into the storage 315, an opening and closing operation of the APC valve 243, a pressure adjusting operation by the APC valve 243 based on the pressure sensor 245, a temperature adjusting operation by the heater 207 based on the temperature sensor 263, a start and stop of the vacuum pump 246, an operation of adjusting a rotation and a rotation speed of the boat 217 by the rotator 267, an elevating and lowering operation of the boat 217 by the boat elevator 115 and an operation of transferring and accommodating the wafer 200 into the boat 217.

The controller 121 may be embodied by installing the above-described program stored in an external memory 123 into the computer. For example, the external memory 123 may include a magnetic tape, a magnetic disk such as a flexible disk and a hard disk, an optical disk such as a CD and a DVD, a magneto-optical disk such as an MO and a semiconductor memory such as a USB memory and a memory card. The memory 121c or the external memory 123 may be embodied by a non-transitory computer readable recording medium. Hereafter, the memory 121c and the external memory 123 are collectively or individually referred to as a “recording medium”. Thus, in the present specification, the term “recording medium” may refer to the memory 121c alone, may refer to the external memory 123 alone, and may refer to both of the memory 121c and the external memory 123. Instead of the external memory 123, a communication interface such as the Internet and a dedicated line may be used for providing the program to the computer.

### (2) Substrate Processing

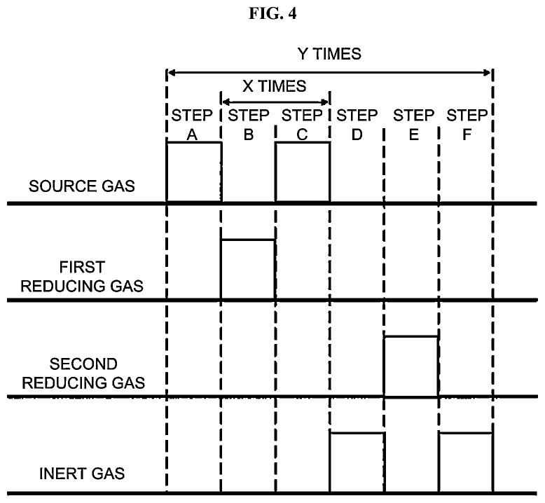

Hereinafter, as a part of a manufacturing process of a semiconductor device, an example of a substrate processing of forming a film containing the first element on the wafer 200 will be described with reference to FIG. 4. The substrate processing of forming the film is performed by using the process furnace 202 of the substrate processing apparatus 10 described above. In the following description, operations of the components constituting the substrate processing apparatus 10 are controlled by the controller 121.

In the substrate processing (that is, the manufacturing process of the semiconductor device) according to the present embodiments, it is possible to form the film containing the first element on the wafer 200 by:
(a) performing a first supply of the source gas containing the first element and the halogen element to the wafer 200;
(b) performing a supply of the first reducing gas to the wafer 200;
(c) performing a supply of the second reducing gas to the wafer 200; and
(d) performing a second supply of the source gas to the wafer 200,
wherein (e) executing (b) and (d) X times without performing a purge between (b) and (d) and (f) executing (e) and (c) Y times are performed.

In the present specification, the term “wafer” may refer to “a wafer itself”, may refer to “a wafer and a stacked structure (aggregated structure) of a predetermined layer (or layers) or a film (or films) formed on a surface of the wafer”. In the present specification, the term “a surface of a wafer” may refer to “a surface of a wafer itself”, may refer to “a surface of a predetermined layer or a film formed on a wafer”. In the present specification, the term “substrate” and “wafer” may be used as substantially the same meaning.

### <Wafer Charging Step and Boat Loading Step>

The wafers 200 are charged (transferred) into the boat 217 (wafer charging step). After the boat 217 is charged with the wafers 200, as shown in FIG. 1, the boat 217 charged with the wafers 200 is elevated by the boat elevator 115 and loaded (transferred) into the process chamber 201 to be accommodated therein (boat loading step). With the boat 217 loaded, the seal cap 219 seals the lower end opening of the outer tube 203 via the O-ring 220b.

### <Pressure Adjusting Step and Temperature Adjusting Step>

The vacuum pump 246 vacuum-exhausts the inner atmosphere of the process chamber 201 such that the inner pressure of the process chamber 201 (that is, a pressure in a space in which the wafers 200 are accommodated) reaches and is maintained at a desired pressure (vacuum degree). Meanwhile, the inner pressure of the process chamber 201 is measured by the pressure sensor 245, and the APC valve 243 is feedback-controlled based on measured pressure information (pressure adjusting step). The vacuum pump 246 continuously vacuum-exhausts the inner atmosphere of the process chamber 201 until at least a processing of the wafer 200 is completed. The heater 207 heats the process chamber 201 such that the inner temperature of the process chamber 201 reaches and is maintained at a desired temperature. Meanwhile, the amount of the current supplied to the heater 207 is feedback-controlled based on the temperature information detected by the temperature sensor 263 such that the desired temperature distribution of the inner temperature of the process chamber 201 is obtained (temperature adjusting step). The heater 207 continuously heats the process chamber 201 until at least the processing of the wafer 200 is completed.

### <Source Gas Supply Step (First Step): Step A>

The valve 314 is opened to supply the source gas into the gas supply pipe 310. A flow rate of the source gas supplied into the gas supply pipe 310 is adjusted by the MFC 312 and stored in the storage 315. The source gas stored in the storage 315 is supplied into the process chamber 201 through the gas supply holes 410a of the nozzle 410, and is exhausted through the exhaust pipe 231. In the present step, in parallel with a supply of the source gas, the valve 514 is opened to supply the inert gas such as the N₂ gas into the gas supply pipe 510. Further, in order to prevent the source gas from entering the nozzles 420 and 430, the valves 524 and 534 are opened to supply the inert gas into the gas supply pipes 520 and 530. Alternatively, in the present step, the source gas may be supplied directly into the process chamber 201 without being stored in the storage 315 (that is, with a zero storage time).

In the present step, for example, the APC valve 243 is appropriately adjusted (or controlled) such that the inner pressure of the process chamber 201 can be set to a pressure within a range from 1 Pa to 3,990 Pa. For example, a supply flow rate of the source gas controlled by the MFC 312 can be set to a flow rate within a range from 0.01 slm to 3.0 slm. For example, each supply flow rate of the inert gas controlled by each of the MFCs 512, 522 and 532 can be set to a flow rate within a range from 0.1 slm to 30.0 slm. Hereinafter, for example, a temperature of the heater 207 can be set such that the temperature of the wafer 200 reaches and is maintained at a temperature within a range from 300° C. to 600° C. Further, in the present specification, a notation of a numerical range such as “from 1 Pa to 3,990 Pa” means that a lower limit and an upper limit are included in the numerical range. Therefore, for example, a numerical range “from 1 Pa to 3,990 Pa” means a range equal to or higher than 1 Pa and equal to or lower than 3,990 Pa. The same also applies to other numerical ranges described in the present specification.

In the present step, the source gas and the inert gas are supplied to the wafer 200. As the source gas, for example, a gas containing the first element and the halogen element (for example, titanium tetrachloride gas (TiCl₄ gas) containing titanium (Ti) and chlorine (Cl)) may be used. When the TiCl₄ gas is used as the source gas, by supplying the TiCl₄ gas, TiClₓ (x is an integer of 4 or less in case of titanium) is adsorbed on the wafer 200 (that is, on a base film on the surface of the wafer 200). Thereby, a titanium-containing layer (Ti-containing layer) is formed.

### <First Reducing Gas Supply Step: Step B>

After a predetermined time has elapsed from the supply of the source gas, the valve 314 is closed and the valve 324 is opened to supply the first reducing gas into the gas supply pipe 320. In other words, after the supply of the source gas is stopped, a supply of the first reducing gas is started. A flow rate of the first reducing gas is adjusted by MFC 322. Then, the first reducing gas whose flow rate is adjusted is supplied into the process chamber 201 through the gas supply holes 420a of the nozzle 420, and is exhausted through the exhaust pipe 231. In the present step, in parallel with the supply of the first reducing gas, the valves 514 and 524 are opened to supply the inert gas into the gas supply pipes 510 and 520. Further, in order to prevent the source gas or the first reducing gas from entering the nozzle 430, the valve 534 is opened to supply the inert gas into the gas supply pipe 530.

In the present step, for example, the APC valve 243 is appropriately adjusted (or controlled) such that the inner pressure of the process chamber 201 can be set to a pressure within a range from 1 Pa to 3,990 Pa. For example, a supply flow rate of the first reducing gas controlled by the MFC 322 can be set to a flow rate within a range from 0.1 slm to 5.0 slm. For example, each supply flow rate of the inert gas controlled by each of the MFCs 512, 522 and 532 can be set to a flow rate within a range from 0.1 slm to 30.0 slm.

In the present step, the first reducing gas and the inert gas are supplied to the wafer 200. As the first reducing gas, for example, a gas containing silicon (Si) and hydrogen (H) such as silane (SiH₄) gas may be used.

By supplying the first reducing gas, for example, hydrogen chloride (HCl) (which serves as a reaction by-product and an adsorption inhibitor) is removed, and an adsorption site where the HCl was adsorbed becomes empty. Thereby, an adsorption site where the TiClₓ can be adsorbed is formed on the surface of the wafer 200. When the adsorption inhibitor is a halide such as the HCl and the first reducing gas is a silane-based compound such as SiH₄, by reacting the HCl and the SiH₄, SiCl₄ and H₂ are generated and exhausted.

Further, it is preferable to perform the first reducing gas supply step (step B) after the source gas supply step (step A) without performing a purge between the step A and the step B. By supplying the first reducing gas after the supply of the source gas without performing the purge, it is possible to reduce an amount of reaction by-products (which are generated by supplying the source gas) adsorbed onto the wafer 200.

### <Source Gas Supply Step (Second Step): Step C>

After a predetermined time has elapsed from the supply of the first reducing gas, the valve 324 is closed to stop the supply of the first reducing gas and the valve 314 is opened to supply the source gas, immediately after the supply of the first reducing gas is stopped, the supply of the source gas is started without performing a purge between the supply of the first reducing gas and the supply of the source gas. The flow rate of the source gas is adjusted by the MFC 312 and stored in the storage 315. The source gas stored in the storage 315 is supplied into the process chamber 201 through the gas supply holes 410a of the nozzle 410, and is exhausted through the exhaust pipe 231. That is, the source gas may be stored in the storage 315 before the present step, and in the present step, the source gas stored in the storage 315 may be supplied into the process chamber 201. In the present step, in parallel with the supply of the source gas, the valve 514 is opened to supply the inert gas into the gas supply pipe 510. Further, in order to prevent the source gas from entering the nozzles 420 and 430, the valves 524 and 534 are opened to supply the inert gas into the gas supply pipes 520 and 530. In the present embodiments, the term “purge” refers to an operation of reducing (or removing) at least the gas present on the wafer 200. For example, the gas present on the wafer 200 may be removed by performing an exhaust of the inner atmosphere (such as an unreacted gas and by-products) of the process chamber 201. In addition, the gas present on the wafer 200 may be removed by performing a pushing out of the gas present in the process chamber 201 by supplying the inert gas into the process chamber 201. For example, the gas present on the wafer 200 may be removed by combining the exhaust described above and the pushing out of the inert gas.

In the present step, for example, the APC valve 243 is appropriately adjusted (or controlled) such that the inner pressure of the process chamber 201 can be set to a pressure within a range from 1 Pa to 3,990 Pa. For example, a supply flow rate of the source gas controlled by the MFC 312 can be set to a flow rate within a range from 0.01 slm to 3.0 slm. For example, each supply flow rate of the inert gas controlled by each of the MFCs 512, 522 and 532 can be set to a flow rate within a range from 0.1 slm to 30.0 slm. In the present step, for example, a supply time (time duration) of supplying the source gas to the wafer 200 can be set to a time within a range from 0.01 second to 20 seconds.

In the present step, the source gas (which is the same as the source gas supplied in the first step described above) and the inert gas are supplied to the wafer 200. When the purge is performed after the step B, the inner atmosphere of the process chamber 201 is vacuum-exhausted, and it takes time to restore the inside of the process chamber 201 to a high pressure state. As a result, the productivity may be reduced. However, according to the present embodiments, by starting the supply of the source gas in the present step after the step B without performing the purge, it is possible to start the present step while maintaining the process chamber 201 at the same high pressure state as in the steps A and B. As a result, it is possible to improve the productivity.

By supplying the source gas in the step C, the gas containing the first element is adsorbed to the adsorption site (which is provided on the surface of the wafer 200) where the first element contained in the source gas can be adsorbed.

Further, the supply amount of the source gas in the step C (second step) is different from the supply amount of the source gas in the step A (first step). Specifically, the supply time of the source gas in the step C is set to be equal to or less than the supply time of the source gas in the step A. In addition, it is preferable that the supply flow rate of the source gas in the step C is set to be equal to or less than the supply flow rate of the source gas in the step A. In the present embodiments, for example, the supply amount is obtained by multiplying the supply time and the supply flow rate. Therefore, the supply amount can be adjusted by adjusting at least one among the supply time and the supply flow rate. Since a substrate processing time can be shortened by shortening the supply time, it is preferable that the supply amount is adjusted by adjusting the supply time.

It is preferable to perform the step C after the step B without performing the purge between the step B and the step C. When the purge is performed after the step B, it takes time before a subsequent supply of the source gas (step C), and the reaction by-products such as SiClₓ and the HCl remaining in the process chamber 201 may re-adhere to the wafer 200. However, according to the present embodiment, by starting the supply of the source gas in the present step after the step B without performing the purge, it is possible to adsorb the TiClₓ onto the wafer 200 before the reaction by-products such as the SiClₓ and the HCl re-adhere to the wafer 200. According to the present embodiments, for example, x is an integer. Further, when the steps B and C are repeatedly performed, the step B is performed after step C without performing the purge.

### <Performing X Times>

By performing a cycle (in which the step B and the step C described above are sequentially performed in this order) at least once, that is, a predetermined number of times (X times, X is an integer of 1 or more), a layer containing the first element and of a predetermined thickness is formed on the wafer 200. That is, a step of performing the step B and the step C X times is performed after the step A. According to the present embodiments, the layer containing the first element may refer to a layer containing the first element and the halogen (which are contained in the source gas). By performing the step B, the reaction by-products generated in at least one among the step A and the step C are removed to form the adsorption site, and in the step C, a ligand containing the first element contained in the source gas can be adsorbed to the adsorption site generated in the step B.

In addition, when X is an integer of 2 or more, the supply time of the source gas in the step C may be decreased with the number of executions where the step C is performed. The supply time of the source gas in the step C may be shortened each time the step C is performed, or the supply time of the source gas in the step C may be shortened whenever a certain number of times of executing the step C are completed. The number of adsorption sites (which are made empty by the step B) decreases by the step C performed after the step B. Thus, by shortening the supply time of the source gas in the step C according to the number of executions where the step C is performed, it is possible to supply the source gas appropriate for the number of the adsorption sites. In other words, it is possible to uniformly adsorb the source gas on the wafer 200 while reducing the consumption of the source gas and shortening the substrate processing time. In other words, the step C serves as a step of bringing an amount of the adsorption of the source gas on the surface of the wafer 200 closer to a saturated state. Therefore, when X is 2 or more, since the source gas is supplied in a state closer to the saturated state in later executions of the step C, most of the source gas supplied to the wafer 200 is exhausted without contributing to the formation of the layer. By adjusting the supply amount in a manner described above, it is possible to optimize the consumption of the source gas. Further, in other words, by repeatedly performing the steps B and C, it is possible to obtain saturation characteristics even though the source gas itself does not inherently exhibit the saturation characteristics. According to the present embodiments, for example, the term “saturation characteristics” may refer to the characteristics of the thickness of the film per cycle with respect to the supply time, and may mean that the thickness of the film per cycle does not increase beyond a predetermined limit after the supply time reaches a certain extent. According to the present embodiments, the statement “the saturation characteristics cannot be obtained” may mean that the predetermined limit is smaller than a theoretical limit and/or the thickness of the film per cycle continues to increase beyond the predetermined limit. In addition, for example, the term “theoretical limit” may refer to a lattice distance per molecule of a constituent material of the film.

### <Purge Step: Step D>

After a predetermined time has elapsed from the supply of the source gas in the second step, the valve 314 is closed to stop the supply of the source gas. In the present step, with the APC valve 243 of the exhaust pipe 231 open, the vacuum pump 246 vacuum-exhausts the inner atmosphere of the process chamber 201 to remove a residual gas from above the wafer 200. Thereby, the source gas (which remains unreacted), the first reducing gas (which remains unreacted) and the reaction by-products remaining in the process chamber 201 are removed from the process chamber 201. Further, in the present step, the valves 514, 524 and 534 are opened to supply the inert gas serving as the purge gas into the process chamber 201. The inert gas acts as the purge gas, which improves an efficiency of removing a substance such as the source gas (which remains unreacted), the first reducing gas (which remains unreacted) and the reaction by-products remaining in the process chamber 201 out of the process chamber 201. For example, each supply flow rate of the inert gas controlled by each of the MFCs 512, 522 and 532 can be set to a flow rate within a range from 0.1 slm to 30.0 slm.

### <Second Reducing Gas Supply Step: Step E>

After a predetermined time has elapsed from the purge step (step D), the valve 334 is opened to supply the second reducing gas into the gas supply pipe 330. A flow rate of the second reducing gas is adjusted by MFC 332. Then, the second reducing gas whose flow rate is adjusted is supplied into the process chamber 201 through the gas supply holes 430a of the nozzle 430, and is exhausted through the exhaust pipe 231. In the present step, in parallel with the supply of the second reducing gas, the valve 534 is opened to supply the inert gas into the gas supply pipe 530. Further, in order to prevent the second reducing gas from entering the nozzles 410 and 420, the valves 514 and 524 are opened to supply the inert gas into the gas supply pipes 510 and 520.

In the present step, for example, the APC valve 243 is appropriately adjusted (or controlled) such that the inner pressure of the process chamber 201 can be set to a pressure within a range from 1 Pa to 3,990 Pa. For example, a supply flow rate of the second reducing gas controlled by the MFC 332 can be set to a flow rate within a range from 0.1 slm to 30.0 slm. For example, each supply flow rate of the inert gas controlled by each of the MFCs 512, 522 and 532 can be set to a flow rate within a range from 0.1 slm to 30.0 slm. In the present step, for example, a supply time (time duration) of supplying the second reducing gas to the wafer 200 can be set to a time within a range from 0.01 second to 30 seconds.

In the present step, the second reducing gas and the inert gas are supplied to the wafer 200. As the second reducing gas, for example, ammonia (NH₃) gas may be used. When the NH₃ gas is used as the second reducing gas, a substitution reaction occurs between the NH₃ gas and at least a portion of the Ti-containing layer formed on the wafer 200. During the substitution reaction, titanium (Ti) contained in the Ti-containing layer and nitrogen (N) contained in the NH₃ gas are bonded together. As a result, a titanium nitride layer (TiN layer) is formed on the wafer 200. Specifically, the TiClₓ adsorbed on the wafer 200 reacts with NH₃ to form a titanium nitride film (TiN film) on the wafer 200 on which an oxide film is formed. Thereby, it is possible to improve a coverage rate of the TiN film. Further, during the substitution reaction, reaction by-products such as the HCl, ammonium chloride (NH₄Cl) and H₂ are generated.

### <Purge Step: Step F>

After a predetermined time has elapsed from the supply of the second reducing gas, the valve 334 is closed to stop the supply of the second reducing gas. In the present step, with the APC valve 243 of the exhaust pipe 231 open, the vacuum pump 246 vacuum-exhausts the inner atmosphere of the process chamber 201 to remove a residual gas from above the wafer 200. Thereby, the second reducing gas (which remains unreacted or which contributed to a formation of the TiN film) and the reaction by-products remaining in the process chamber 201 are removed from the process chamber 201. Further, in the present step, the valves 514, 524 and 534 are opened to supply the inert gas serving as the purge gas into the process chamber 201. The inert gas acts as the purge gas, which improves an efficiency of removing a substance such as the second reducing gas (which remains unreacted or which contributed to the formation of the TiN film) and the reaction by-products remaining in the process chamber 201 out of the process chamber 201. For example, each supply flow rate of the inert gas controlled by each of the MFCs 512, 522 and 532 can be set to a flow rate within a range from 0.1 slm to 30.0 slm.

### <Performing Y Times>

By performing a cycle (in which the step A to the step F described above are sequentially performed in this order) at least once, that is, a predetermined number of times (Y times, Y is an integer of 1 or more), a film containing the first element and of a predetermined thickness is formed on the wafer 200. According to the present embodiments, for example, the titanium nitride film (TiN film) is formed on the wafer 200.

### <After-Purge Step and Returning to Atmospheric Pressure Step>

The inert gas is supplied into the process chamber 201 through each of the gas supply pipes 510, 520 and 530, and is exhausted through the exhaust pipe 231. The inert gas serves as the purge gas, and the inner atmosphere of the process chamber 201 is purged with the inert gas. Thus, the residual gas in the process chamber 201 and the reaction by-products remaining in the process chamber 201 are removed from the process chamber 201 (after-purge step). Thereafter, the inner atmosphere of the process chamber 201 is replaced with the inert gas (substitution by inert gas), and the inner pressure of the process chamber 201 is returned to a normal pressure (atmospheric pressure) (returning to atmospheric pressure step).

### <Boat Unloading Step and Wafer Discharging Step>

Thereafter, the seal cap 219 is lowered by the boat elevator 115 and the lower end of the outer tube 203 is opened. The boat 217 with the wafers (which are processed) 200 charged therein is unloaded out of the outer tube 203 through the lower end of the outer tube 203 (boat unloading step). Then, the wafers (which are processed) 200 are discharged (transferred) out of the boat 217 (wafer discharging step).

### (3) Effects According to Present Embodiments

According to the present embodiments, it is possible to obtain one or more of the following effects.
(a) It is possible to improve the coverage rate of the film.
(b) It is possible to improve a continuity of the film. In the present embodiments, the term “continuity” may mean that crystals of a material of the film are connected, a gap between the crystals is small, and the like.
(c) It is possible to improve the characteristics of the film formed on the substrate (wafer 200).
(d) By performing the steps (the steps B and C) X times, it is possible to increase the amount of the source gas adsorbed onto the wafer 200.
(e) By performing the steps (the steps B and C) X times, even when employing the source gas whose adsorption characteristics on the surface of the wafer 200 do not exhibit saturation, it is possible to get closer to a saturated adsorption state.

### (4) Other Embodiments

The technique of the present disclosure is described in detail by way of the embodiments mentioned above. However, the technique of the present disclosure is not limited thereto. The technique of the present disclosure may be modified in various ways without departing from the scope thereof.

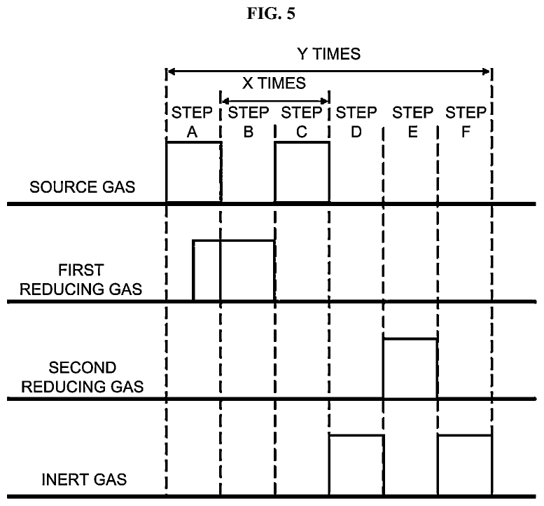

For example, a substrate processing sequence shown in FIG. 5 may be used. In the substrate processing sequence shown in FIG. 5, the valve 324 is opened during the supply of the source gas in step A mentioned above, and the supply of the first reducing gas is started. That is, the first reducing gas is supplied before the step A (first step) is ended (completed). Even in such a case, it is possible to obtain substantially same effects as those of the embodiments mentioned above. For example, it is possible to improve a coverage rate of TiCl, and it is also possible to improve the continuity of the titanium-containing film such as the TiN film. Thereby, it is possible to improve a step coverage performance of the film formed in a trench provided at the wafer 200. Further, it is possible to remove the reaction by-products generated during the step A from the process chamber 201.

For example, the embodiments mentioned above are described by way of an example in which the source gas is supplied in the second step after the supply of the first reducing gas without performing the purge. However, the technique of the present disclosure is not limited thereto. For example, the source gas may be supplied in the second step after performing the purge for a short period of time after the supply of the first reducing gas.

For example, the embodiments mentioned above are described by way of an example in which the TiCl₄ gas containing titanium (Ti) and chlorine (Cl) is used as the gas containing the first element and the halogen element (that is, as the source gas). However, the technique of the present disclosure is not limited thereto. For example, the technique of the present disclosure may be preferably applied when a gas containing the halogen element and at least one among other metal elements, a transition metal element and a Group 14 element is used as the source gas.

For example, the Group 14 element may include silicon (Si) and germanium (Ge). When silicon is used as the Group 14 element, a gas containing silicon and the halogen element (that is, a halosilane gas) may be used. The halogen element may refer to an element such as chlorine (CI), fluorine (F), bromine (Br) and iodine (I). As the halosilane gas, for example, a chlorosilane gas containing silicon (Si) and chlorine (Cl) may be used.

Specifically, as the source gas, for example, a chlorosilane gas such as monochlorosilane (SiH₃Cl, abbreviated as MCS) gas, dichlorosilane (SiH₂Cl₂, abbreviated as DCS) gas, trichlorosilane (SiHCl₃, abbreviated as TCS) gas, tetrachlorosilane (SiCl₄, abbreviated as 4CS) gas, hexachlorodisilane (Si₂Cl₆, abbreviated as HCDS) gas and octachlorotrisilane (Si₃Cl₈, abbreviated as OCTS) gas may be used. For example, one or more of the gases exemplified above as the chlorosilane gas may be used as the source gas.

Further, as the other metal elements (which include the transition metal element), an element such as hafnium (Hf), zirconium (Zr), aluminum (Al), molybdenum (Mo) and tungsten (W) may be used. For example, the technique of the present disclosure may be preferably applied when a gas containing the halogen element and at least one among the other metal elements exemplified above is used.

For example, as the source gas, a gas such as hafnium tetrachloride (HfCl₄) gas, zirconium tetrachloride (ZrCl₄) gas, aluminum trichloride (AlCl₃) gas, molybdenum dichloride dioxide (MoO₂Cl₂) gas and tungsten hexafluoride (WF₆) gas may be used.

For example, the embodiments mentioned above are described by way of an example in which the SiCl₄ gas is used as the first reducing gas. However, the technique of the present disclosure is not limited thereto. It is sufficient that a gas containing hydrogen (H) is used as the first reducing gas. For example, the technique of the present disclosure may be preferably applied when a silane-based gas such as disilane (Si₂H₆) and trisilane (Si₃H₈) or a borane-based gas such as monoborane (BH₃) or diborane (B₂H₆) is used.

For example, the embodiments mentioned above are described by way of an example in which the NH₃ gas is used as the second reducing gas. However, the technique of the present disclosure is not limited thereto. It is sufficient that a gas containing hydrogen (H) is used as the second reducing gas. For example, the technique of the present disclosure may be preferably applied when a nitrogen-containing gas such as diazene (N₂H₂), triazene (N₃H₃) and hydrazine (N₂H₄) is used.

For example, the embodiments mentioned above are described by way of an example in which a vertical batch type substrate processing apparatus configured to simultaneously process a plurality of substrates is used to form the film. However, the technique of the present disclosure is not limited thereto. For example, the technique of the present disclosure may be preferably applied when a single wafer type substrate processing apparatus configured to process one or several substrates at a time is used to form the film.

It is preferable that the process recipe (that is, a program defining parameters such as the process procedures and the process conditions of the substrate processing) used to form various films mentioned above is prepared individually in accordance with the contents of the substrate processing such as a type of the film to be formed, a composition ratio of the film, a quality of the film, a thickness of the film, the process procedures and the process conditions of the substrate processing. That is, a plurality of process recipes are prepared. Then, when starting the substrate processing, an appropriate process recipe is preferably selected among the process recipes in accordance with the contents of the substrate processing. Specifically, it is preferable that the process recipes are stored in the memory 121c of the substrate processing apparatus in advance via an electric communication line or the recording medium (for example, the external memory 123) storing the process recipes prepared individually in accordance with the contents of the substrate processing. Then, when starting the substrate processing, the CPU 121a preferably selects the appropriate process recipe among the process recipes stored in the memory 121c of the substrate processing apparatus in accordance with the contents of the substrate processing. With such a configuration, various films of different types, different composition ratios, different qualities and different thicknesses can be universally formed in a reliably reproducible manner by using a single substrate processing apparatus. In addition, since a burden on an operating personnel such as inputting the process procedures and the process conditions can be reduced, various processes can be performed quickly while avoiding an error in operating the substrate processing apparatus.

Further, the technique of the present disclosure may be implemented by changing an existing process recipe stored in the substrate processing apparatus to a new process recipe. When changing the existing process recipe to the new process recipe, the new process recipe may be installed in the substrate processing apparatus via the electric communication line or the recording medium storing the process recipes. Alternatively, the existing process recipe already stored in the substrate processing apparatus may be directly changed to the new process recipe according to the technique of the present disclosure by operating the input/output device of the substrate processing apparatus.

Further, for example, the technique of the present disclosure may be used in a structure such as a word line of a DRAM and a 3D NAND flash memory of a three-dimensional structure.

While the technique of the present disclosure is described in detail by way of the embodiments and the modified examples mentioned above, the technique of the present disclosure is not limited thereto. The technique of the present disclosure may be applied even when the embodiment and the modified examples mentioned above are appropriately combined.

According to some embodiments of the present disclosure, it is possible to improve the characteristics of the film formed on the substrate.

What is claimed is:

1. A substrate processing method comprising:
(a) performing a first supply of a source gas containing a first element and a halogen element to a substrate;
(b) performing a supply of a first reducing gas to the substrate;
(c) performing a supply of a second reducing gas to the substrate; and
(d) performing a second supply of the source gas to the substrate,
wherein (e) executing (b) and (d) X times without performing a purge between (b) and (d) and (f) executing (e) and (c) Y times are performed.

2. The substrate processing method of claim 1, wherein (e) is performed after (a).

3. The substrate processing method of claim 1, further comprising
(b2) supplying the first reducing gas after (a) is started and before (e) is started.

4. The substrate processing method of claim 1, wherein, in (e), (d) is performed after (b).

5. The substrate processing method of claim 2, wherein, in (e), (d) is performed after (b).

6. The substrate processing method of claim 3, wherein, in (e), (d) is performed after (b).

7. The substrate processing method of claim 1, wherein (b) is performed after (a) without performing the purge between (a) and (b).

8. The substrate processing method of claim 2, wherein (b) is performed after (a) without performing the purge between (a) and (b).

9. The substrate processing method of claim 3, wherein (b) is performed after (a) without performing the purge between (a) and (b).

10. The substrate processing method of claim 4, wherein (b) is performed after (a) without performing the purge between (a) and (b).

11. The substrate processing method of claim 1, wherein a supply amount of the source gas in (a) is set to be different from that of the source gas in (d).

12. The substrate processing method of claim 2, wherein a supply amount of the source gas in (a) is set to be different from that of the source gas in (d).

13. The substrate processing method of claim 4, wherein a supply amount of the source gas in (a) is set to be different from that of the source gas in (d).

14. The substrate processing method of claim 7, wherein a supply amount of the source gas in (a) is set to be different from that of the source gas in (d).

15. The substrate processing method of claim 1, wherein a supply time of the source gas in (d) is set to be equal to or less than that of the source gas in (a).

16. The substrate processing method of claim 1, wherein a supply flow rate of the source gas in (d) is set to be equal to or less than that of the source gas in (a).

17. The substrate processing method of claim 1, wherein, in (e), a supply time of the source gas in (d) is set to be decreased with the number of executions of (d).

18. A method of manufacturing a semiconductor device, comprising the substrate processing method of claim 1.

19. A non-transitory computer-readable recording medium storing a program that causes a substrate processing apparatus, by a computer, to perform:
(a) performing a first supply of a source gas containing a first element and a halogen element to a substrate;
(b) performing a supply of a first reducing gas to the substrate;
(c) performing a supply of a second reducing gas to the substrate; and
(d) performing a second supply of the source gas to the substrate,
wherein (e) executing (b) and (d) X times without performing a purge between (b) and (d) and (f) executing (e) and (c) Y times are performed.

20. A substrate processing apparatus comprising:
a process vessel in which a substrate is accommodated;
a first gas supplier configured to supply a source gas containing a first element and a halogen element to the substrate;
a second gas supplier configured to supply a first reducing gas to the substrate;
a third gas supplier configured to supply a second reducing gas to the substrate; and
a controller configured to be capable of controlling the first gas supplier, the second gas supplier and the third gas supplier to perform:
(a) performing a first supply of the source gas containing the first element and the halogen element to the substrate;
(b) performing a supply of the first reducing gas to the substrate;
(c) performing a supply of the second reducing gas to the substrate; and
(d) performing a second supply of the source gas to the substrate,
wherein (e) executing (b) and (d) X times without performing a purge between (b) and (d) and (f) executing (e) and (c) Y times are performed.
